(19) United States
(12) Patent Application Publication
(10) Pub. No.: US 2009/0065854 A1
(43) Pub. Date: Mar. 12, 2009

(54) Semiconductor Device and Method of Fabricating the Same

(76) Inventor: CHANG YOUNG JU, Bucheon-si (KR)

Correspondence Address: Chang Young JU, 1402-1403,Yeonhwa Maeul Apt., Jung 2-dong,, Wonmi-gu, Bucheon-si, Gyeonggi-do, KR

(21) Appl. No.: 12/204,993

(22) Filed: Sep. 5, 2008

(30) Foreign Application Priority Data
Sep. 7, 2007 (KR) 10-2007-0090748

(51) Int. Cl. H01L 29/78; H01L 21/336

(52) U.S. Cl. 257/327; 438/268; 257/E29.262; 257/E21.41

(57) ABSTRACT

Disclosed are a semiconductor device and a method of fabricating the same. The semiconductor device includes second-conductive-type drift areas formed in a first-conductive-type well of a semiconductor substrate while being spaced apart from each other a vertical area protruding from the drift areas, and a second-conductive-type source/drain area formed on the vertical area. The vertical area can provide an extended drift area for a current path

### CROSS-REFERENCE TO RELATED APPLICATION

The present application claims the benefit under 35 U.S.C. §119 of Korean Patent Application No. 10-2007-0090748, filed Sep. 7, 2007, which is hereby incorporated by reference in its entirety.

### BACKGROUND

Currently, a high-voltage semiconductor device is being extensively used in application fields such as communication, home appliances, display apparatus, and automobiles. These application fields are being gradually enlarged. The high voltage semiconductor device utilizes a high-voltage transistor. In many fields, the high-voltage transistor requires a high breakdown voltage.

### BRIEF SUMMARY

Embodiments of the present invention provide a semiconductor device having a high breakdown voltage and a method of fabricating the same.

A semiconductor device according to an embodiment can include second conductive type drift areas formed in a first-conductive type well of a semiconductor substrate while being spaced apart from each other, a vertical area protruding from the drift areas, and a second conductive type source/drain area formed on the vertical area.

A method of fabricating a semiconductor device according to an embodiment can include forming a well by implanting first conductive type impurities into a semiconductor substrate; forming drift areas by implanting second conductive type impurities into the well, the drift areas being spaced apart from each other; forming a vertical area protruding from the drift areas; and forming a source/drain area by implanting second conductive type impurities into the vertical area.

The semiconductor device according to embodiments includes a vertical area protruding from the substrate and source/drain areas formed on the vertical area. The vertical area can extend the height of the drift regions above the surface of the substrate.

Accordingly, the path of a current applied to the source/drain area is lengthened by a height of the vertical area. The semiconductor device according to an embodiment is operable at high voltage, and has a high breakdown voltage.

In addition, since the current path is lengthened in a vertical direction, the size of the subject semiconductor device in the horizontal direction can be identical to or smaller than that of a conventional semiconductor device, while providing a breakdown voltage identical to or higher than that of the conventional semiconductor device.

### BRIEF DESCRIPTION OF THE DRAWINGS

FIG. 1 is a cross-sectional view showing a high-voltage transistor according to an embodiment of the present invention.

FIGS. 2A to 2H are cross-sectional views showing a method of fabricating a high-voltage transistor according to an embodiment of the present invention.

### DETAILED DESCRIPTION

Hereinafter, embodiments of a high-voltage transistor and method of fabricating the same are provided.

Although the following description of embodiments indicate a particular conductive-type for elements, embodiments are not limited thereto. For example, it is within the spirit and scope of the disclosure to include a p-type high voltage transistor.

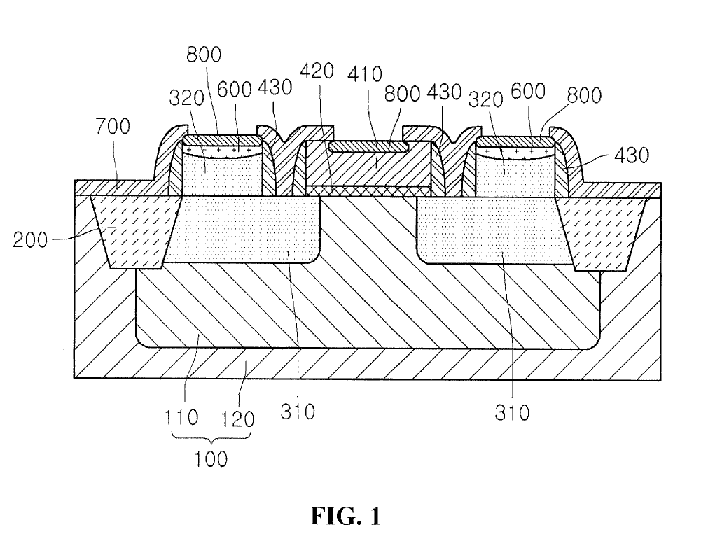

Referring to FIG. 1, a high-voltage transistor according to an embodiment includes a gate insulating layer 420, a gate electrode 410, drift areas 310, vertical areas 320, source/drain areas 600, spacers 430, silicide layers 800, and a protective layer 700. The high-voltage transistor can be formed on a semiconductor substrate 100.

According to certain embodiments, the semiconductor substrate 100 can include a P well 110 including P-type impurities and an area 120 including N-type impurities.

An isolation layer 200 can be provided in the semiconductor substrate 100. The isolation layer 200 insulates devices formed in the semiconductor substrate 100 from each other. In an embodiment, the isolation layer 200 can include an oxide. The isolation layer 200 can be formed through, for example, a shallow trench isolation (STI) process or a local oxidation of silicon (LOCOS) process.

The gate insulating layer 420 can be formed on the semiconductor substrate 100. In one embodiment, the gate insulating layer 420 can include a silicon oxide (e.g., SiO₂).

The gate electrode 410 can be formed on the gate insulating layer 420. In an embodiment, the gate electrode 410 can include polycrystalline silicon (polysilicon).

The drift area 310 can be formed in the P well 110. In particular, the drift area 310 can be formed in the P well 110 of the substrate 100 corresponding to side portions of the gate electrode 410. Two drift areas 310 can be spaced apart from each other by a predetermined distance (corresponding to a first side portion and a second side portion of the gate electrode 410). The drift areas 310 can be implanted with N-type impurities having a first concentration.

A channel area is formed corresponding to the space between the two drift areas 310. The gate insulating layer 420 and the gate electrode 410 are provided on the channel area of the substrate.

The vertical area 320 protrudes from the drift areas 310. For example, the vertical areas 320 can be provided on each of the two drift areas 310. In an embodiment, the vertical area 320 can be formed through an epitaxial process. The vertical area 320 can be implanted with N-type impurities having a second concentration.

In certain embodiments, a top surface of the vertical area 320 can be higher than the gate electrode 410. In another embodiment, a top surface of the vertical area 320 can be lower than the gate electrode 410.

In one embodiment, the second concentration of N-type impurities in the vertical area 320 can be identical to the first concentration of N-type impurities in the drift area 310. In another embodiment, the second concentration can be higher than the first concentration. The first and second concentrations can be selectively adjusted to obtain a high-voltage transistor having a desired characteristic.

A spacer 430 can be provided at side surfaces of the gate electrode 410 and the vertical areas 320.

The source/drain areas 600 can be formed on respective vertical areas 320. The source/drain areas 600 can include N-type impurities having a concentration higher than the first and second concentrations.

When a current is applied to the source/drain areas 600, the current path includes the vertical area 320. In other words, the current path becomes lengthened by the height of the vertical area 320 as compared with that of a high-voltage transistor having no vertical area 320.

In addition, the distance between the source/drain areas 600 and the area 120 including N-type impurities of the semiconductor substrate 100 becomes lengthened as compared with that of a high-voltage transistor having no vertical area 320.

Accordingly, even if a high voltage is applied to the source/drain area 600, the high-voltage transistor according to embodiments can be normally operated. Therefore, a breakdown voltage of the subject high-voltage transistor is higher than that of a high-voltage transistor having no vertical area 320.

In addition, since the vertical area 320 protrudes from the drift area 310, the current path becomes lengthened in the vertical direction. Accordingly, even if the high-voltage transistor of an embodiment has a breakdown voltage identical to or higher than that of a conventional high-voltage transistor, the size of the high-voltage transistor of this embodiment in the horizontal direction can be identical to or smaller than that of the conventional high-voltage transistor.

The spacers 430 can be provided at the side surfaces of the gate electrode 410 and the vertical areas 320. The spacers 430 insulate the side surfaces of the gate electrode 410 and the vertical areas 320. In an embodiment, the spacers 430 can include a nitride.

The silicide layers 800 include silicide. The silicide layers 800 can be provided on the source/drain areas 600 and the gate electrodes 410. The silicide layer 800 can electrically connect the source/drain area 600 and the gate electrode 410 with interconnections (not shown) provided on the silicide layer 800.

The protective layer 700 can cover portions of the substrate including the spacer 430 and the drift area 310. In an embodiment, the protective layer 700 can include oxide. The protective layer 700 can cover the spacers 430 and the drift areas 310 while exposing regions for the silicide layer 800.

The silicide layer 800 can be provided thereon with interconnections electrically connected to another semiconductor device,

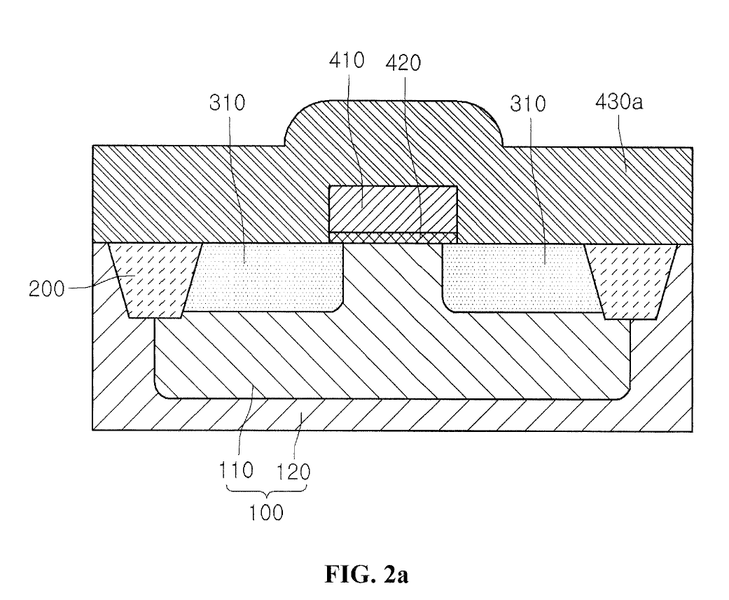

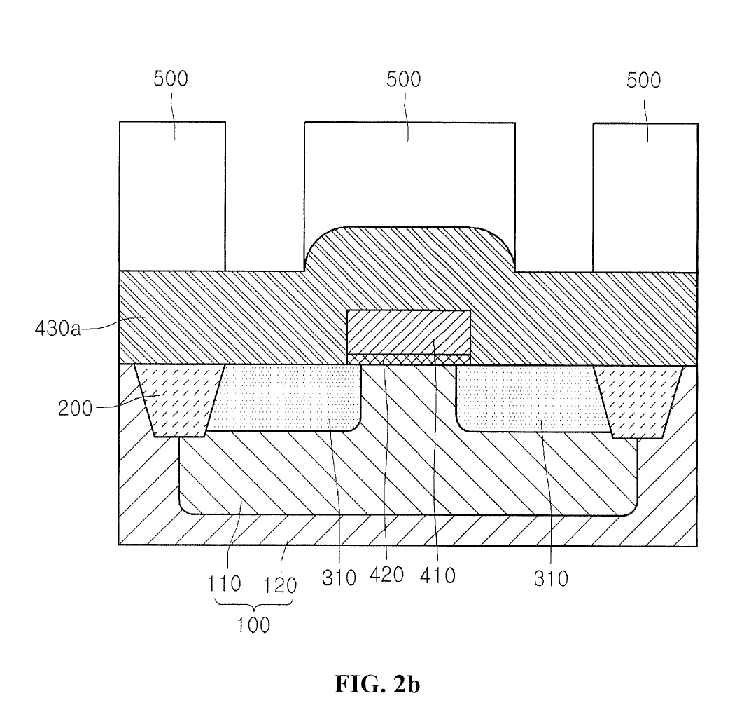

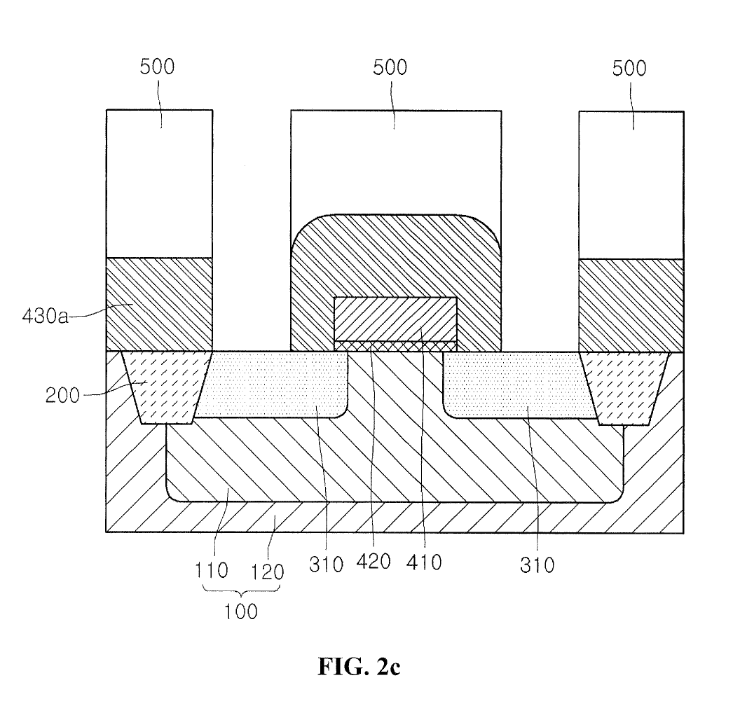

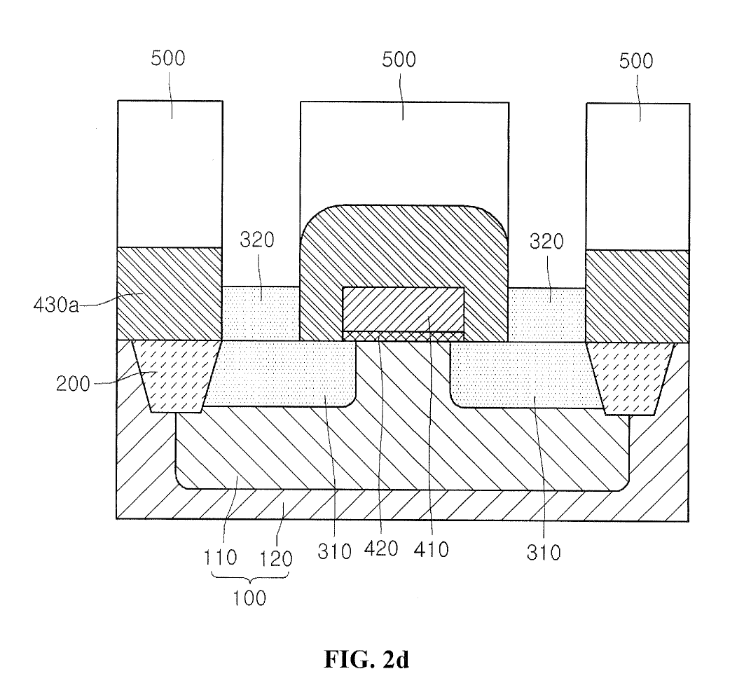

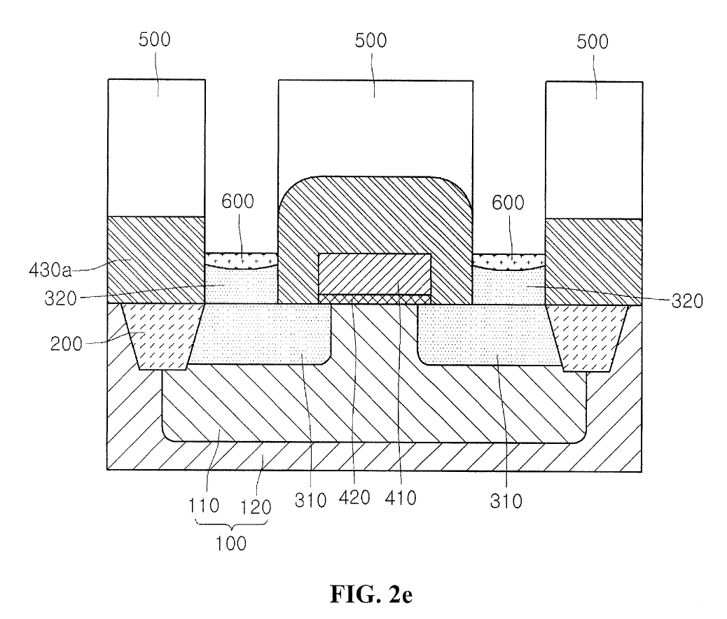

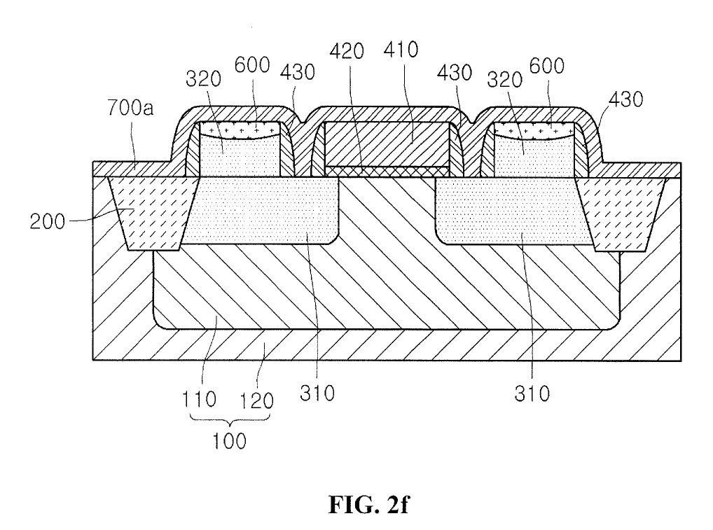

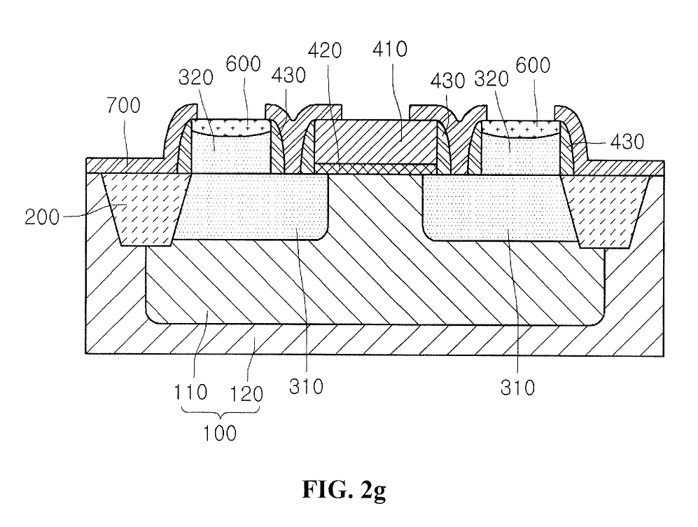

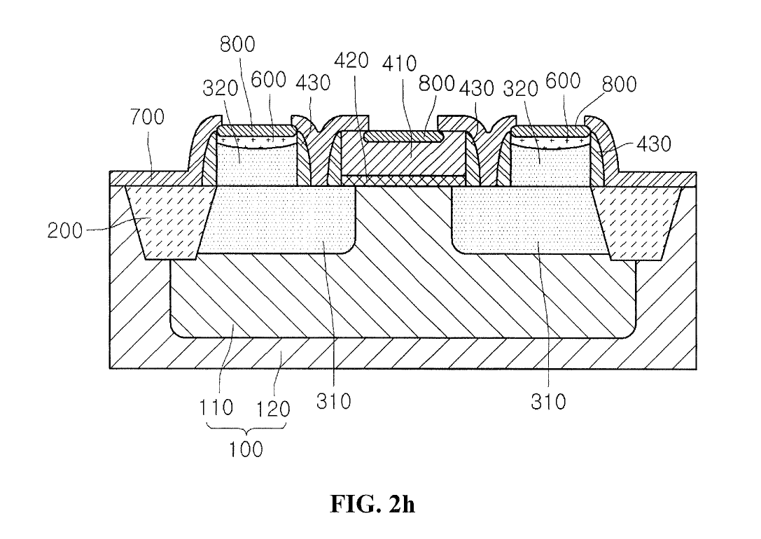

A method of fabricating the high-voltage transistor according to an embodiment will be described with reference to FIGS. 2A to 2H.

Referring to FIG. 2A, a trench can be formed in a semiconductor substrate 100 including N-type impurities. An oxide can be filled in the trench to form an isolation layer 200.

Thereafter, P-type impurities can be implanted into regions of the substrate 100 defined by the isolation layer 200 to form a P well 110. At this point, the semiconductor substrate 100 can include the P well 110 and the area including N-type impurities.

N-type impurities having a first concentration can be implanted in a predetermined area of the P well 110 to form the drift areas 310. Two drift areas 310 can be formed in the P well 110 spaced apart from each other by a predetermined distance. A n area between the drift areas 310 can define a channel area.

Thereafter, through a thermal oxidation process, an oxide layer can be formed on the semiconductor substrate 100, and a polysilicon layer can be formed on the oxide layer. The oxide layer and the polysilicon layer can be patterned by a mask process to provide a gate insulating layer 420 and a gate electrode 410 on the channel area.

After the gate electrode 410 is formed, a nitride layer 430a can be formed on the semiconductor substrate 100 to cover the gate electrode 410 and the drift area 310.

Referring to FIG. 2B, a photoresist film can be formed on the nitride layer 430a, and a photoresist pattern 500 can be formed from the photoresist film through a photo process including an exposure and development process. The photoresist pattern 500 exposes a portion of the nitride layer 430a corresponding to the drift areas 310.

Referring to FIG. 2C, the exposed portions of the nitride layer 430a can be etched by using the photoresist pattern 500 as an etching mask to expose a portion of the drift areas 310.

Referring to FIG. 2D, after the nitride layer 430a is etched, an epitaxial layer can be formed on the exposed portion of the drift areas 310. In one embodiment, the epitaxial layer can be formed through a vapor phase epitaxy (VPE) process. In another embodiment, the epitaxial layer can be formed, for example, through a molecular beam epitaxy (MBE) process. According to embodiments, the epitaxial layer can be formed to a height lower, the same, or higher than the height of the gate electrode 410.

After the epitaxial layer is formed, N-type impurities having a second concentration can be implanted into the epitaxial layer to provide the vertical area 320 formed on the drift area 310. In an embodiment, the second concentration can be identical to the first concentration. In another embodiment, the second concentration can be higher than the first concentration.

Referring to FIG. 2E, N-type impurities having a third concentration can be implanted into the vertical area 320, thereby forming the source/drain areas 600. T he third concentration can be higher than the first and second concentrations.

Referring to FIG. 2F, after the source/drain areas 600 are formed, the photoresist pattern 500 can be removed through an ashing process.

The nitride layer 430a can be etched through an anisotropic etching process, such as an etch back process to provide spacers 430 at side surfaces of the gate electrode 410 and the vertical areas 320. The spacers 430 can protect the side surfaces of the gate electrode 410 and the vertical area 320.

Thereafter, an oxide layer 700a can be formed to cover the semiconductor substrate 100. The oxide layer 700a can cover the spacers 430, the gate electrode 410, the vertical areas 320, and the drift areas 310.

Referring to FIG. 2G, after the oxide layer 700a is formed, the oxide layer 700a can be etched such that a portion of the source/drain areas 600 and the gate electrode 410 are exposed, thereby forming the protective layer 700. The protective layer 700 can protect the spacers 430 and the drift area 310 during a subsequent silicide formation process.

Referring to 2H, after the protective layer 700 is formed, a metal layer can be formed covering the semiconductor substrate 100. The metal layer can include, for example, nickel (Ni), titanium (Ti), tantalum (Ta), or platinum (Pt).

After the metal layer is formed, the silicide layers 800 can be formed on the exposed portions of source/drain area 600 and the gate electrode 410 through rapid temperature processing (RTP). After the silicide layer 800 is formed, the metal layer not subject to the above reaction (e.g. unreacted metal), can be removed by a cleaning solution.

Thereafter, interconnections electrically connected to the silicide layer 800 can be formed on the silicide layer 800.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a First second-conductive-type drift area spaced apart from a second second-conductive-type drift area in a first-conductive-type well of a semiconductor substrate;
a vertical area protruding from the first second-conductive type drift area and the second second-conductive-type drift area, respectively; and
a second-conductive-type source/drain area on the vertical area.

2. The semiconductor device according to claim 1, further comprising a gate electrode disposed between the vertical area protruding from the first second-conductive-type drift area and the vertical area protruding from the second second-conductive-type drift area.

3. The semiconductor device according to claim 2, further comprising a spacer at side surfaces of the gate electrode and the vertical areas.

4. The semiconductor device according to claim 1, wherein the vertical area comprises second-conductive-type impurities.

5. The semiconductor device according to claim 4, wherein the vertical area has a concentration of second-conductive-type impurities higher than the concentration of second-conductive-type impurities of the drift areas.

6. The semiconductor device according to claim 4, wherein the vertical area has a concentration of second-conductive-type impurities substantially the same as the concentration of second-conductive-type impurities of the drift areas.

7. The semiconductor according to claim 4, wherein the vertical area comprises an epitaxial layer grown on the drift areas and implanted with the second-conductive-type impurities.

8. A high-voltage transistor comprising:
a well comprising first-conductive-type impurities in a semiconductor substrate;
drift areas comprising second-conductive-type impurities spaced apart from each other in the well;
a channel area provided in the spaced apart region between the drift areas;
a gate electrode disposed on the channel area; and
a vertical area protruding from the drift areas while being laterally spaced apart from the gate electrode.

9. The high-voltage transistor according to claim 8, wherein a height of the vertical area is higher than a height of the gate electrode.

10. The high-voltage transistor according to claim 8, further comprising source/drain areas on the vertical area.

11. The high-voltage transistor according to claim 10, further comprising silicide on the source/drain areas and the gate electrode.

12. The high-voltage transistor according to claim 8, wherein the vertical area comprises second-conductive-type impurities, wherein the second-conductive-type impurities of the vertical area have a concentration higher than the concentration of the second-conductive-type impurities of the drift areas.

13. The high-voltage transistor according to claim 8, further comprising a spacer at a side surface of the vertical area.

14. A method of fabricating a semiconductor device, the method comprising:
forming a well by implanting first-conductive-type impurities into a semiconductor substrate;
forming drift areas by implanting second-conductive-type impurities into the well, the drift areas being spaced apart from each other;
forming a vertical area protruding from the drift areas; and
forming a source/drain area by implanting second-conductive-type impurities into the vertical area.

15. The method according to claim 14, wherein the forming of the vertical area comprises:
forming a mask layer on the semiconductor substrate exposing a portion of the drift areas;
forming an epitaxial layer on the exposed portion of the drift areas; and
implanting second-conductive-type impurities into the epitaxial layer.

16. The method according to claim 15, wherein, the second-conductive-type impurities of the epitaxial layer have a second concentration higher than a first concentration of the second conductive type impurities implanted into the well area to form the drift areas.

17. The method according to claim 15, wherein in the forming of the source/drain area, the second-conductive-type impurities are implanted into the epitaxial layer using the mask layer as a mask.

18. The method according to claim 14, further comprising forming a silicide layer on the source/drain area.

19. The method according to claim 14, further comprising, after forming the drift areas, forming a gate electrode and gate insulating layer on a region of the semiconductor substrate between the spaced apart drift areas.

20. The method according to claim 19, further comprising forming a spacer on sidewalls of the gate electrode and the vertical area.
